(19) United States
(12) Patent Application Publication
(10) Pub. No.: US 2025/0364466 A1
(43) Pub. Date: Nov. 27, 2025

(54) ELECTRONIC DEVICE AND A METHOD FOR FORMING THE SAME

(71) Applicant: STATS ChipPAC Pte. Ltd., Singapore (SG)

(72) Inventors: SeokBeom HEO, Incheon (KR); SeongKuk KIM, Gyeonggi-do (KR); SoYeong PARK, Incheon (KR); HeeYoun KIM, Incheon (KR); HyunMi PARK, Incheon (KR)

(21) Appl. No.: 19/215,386

(22) Filed: May 22, 2025

(30) Foreign Application Priority Data
May 22, 2024 (CN) 202410639960.6

(51) Int. Cl. H01L 23/00

(52) U.S. Cl. CPC H01L 24/09; H01L 24/03; H01L 24/05; H01L 24/06; H01L 24/08; H01L 24/81; H01L 2224/1132; H01L 2224/13021; H01L 2224/1403; H01L 2224/16227; H01L 2224/17517; H01L 2224/81024; H01L 2224/81815

(57) ABSTRACT

A method for forming an electronic device is provided. The method comprises: providing a package substrate with a first set of conductive pads formed thereon; forming supporting components on the package substrate without covering the first set of conductive pads; depositing a solder material onto the first set of conductive pads; mounting an electronic component having a second set of conductive pads onto the package substrate to align each of the first set of conductive pads with one of the second set of conductive pads; and reflowing the solder material to electrically connect the electronic component with the package substrate through the first and second sets of conductive pads, wherein the electronic component is supported by the supporting components during the reflowing.

### TECHNICAL FIELD

The present application generally relates to semiconductor technology, and more particularly, to an electronic device and a method for forming the same.

### BACKGROUND OF THE INVENTION

In a semiconductor fabrication process, an electronic component may be mounted onto a substrate (e.g., a printed circuit board) via solder bumps therebetween. Typically, solder paste may first be applied on the substrate and the electronic component may then be attached on the solder paste. The solder paste may go through a reflowing process subsequently to form solder bumps, which enable electrical connection between the substrate and the electronic component thereon. To be more specific, a typical solder paste material may include flux and solder powders. During the reflowing process, the solder powders may melt and be reshaped, and at the same time, the flux may be activated and vaporized, and bubbles of the vaporized flux may be generated. However, in the reflowing process, the melted solder powders may be pressed against the substrate by the electronic component mounted thereon, especially for a large electronic component with a heavy weight. As such, a gap between the substrate and the electronic component may be decreased, which may prevent the vaporized flux gas from escaping to the outside through the gap. The trapped flux gas may result in defects within the solder bumps after the reflowing process, and thus adversely affect bonding performance between the substrate and the electronic component.

Therefore, a need exists for a method for forming an electronic device with an improved bonding quality between a substrate and an electronic component through solder bumps.

### SUMMARY OF THE INVENTION

An objective of the present application is to provide a method for forming an electronic device with an improved bonding quality between a substrate and an electronic component through solder bumps.

According to an aspect of the present application, a method for forming an electronic device is provided. The method comprises: providing a package substrate with a first set of conductive pads formed thereon; forming supporting components on the package substrate without covering the first set of conductive pads; depositing a solder material onto the first set of conductive pads; mounting an electronic component having a second set of conductive pads onto the package substrate to align each of the first set of conductive pads with one of the second set of conductive pads; and reflowing the solder material to electrically connect the electronic component with the package substrate through the first and second sets of conductive pads, wherein the electronic component is supported by the supporting components during the reflowing.

According to another aspect of the present application, an electronic device is provided. The electronic device comprises: a package substrate with a first set of conductive pads formed thereon; supporting components formed on the package substrate and exposing the first set of conductive pads; an electronic component mounted on the package substrate via solder bumps and the supporting components, wherein the electronic component has a second set of conductive pads each being aligned with one of the first set of conductive pads and connected with the conductive pad via one of the solder bumps, and wherein the electronic component is electrically coupled to the package substrate through the first and second sets of conductive pads and the solder bumps therebetween.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1G illustrate various steps of a method for forming an electronic device according to a first embodiment of the present application.

FIG. 2 illustrates an electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, an electronic component may be mounted onto a substrate via solder bumps. Typically, solder paste may first be applied on the substrate and the electronic component may then be attached on the solder paste. The solder paste may go through a reflowing process subsequently to form the solder bumps, which enable electrical connection between the substrate and the electronic component thereon. A typical solder paste material may include flux and solder powders. During a reflowing process, the solder powders may melt and be reshaped, and at the same time, the flux may be activated and vaporized, and bubbles of the vaporized flux may be generated.

However, the melted solder powders may be pressed against the substrate by the electronic component during the reflowing process. As such, a gap between the substrate and the electronic component may be decreased, which may prevent the vaporized flux from escaping to the outside through the gap. This results in defects within the solder bumps after the reflowing process. To be more specific, the trapped gas may lead to voids in the solder bumps and beadings between the substrate and the electronic component, which adversely affect bonding performance between the substrate and the electronic component and increase short-circuit risks.

To address this issue, a new method for forming an electronic device is provided, which introduces supporting components on a substrate to support an electronic component thereon during a reflowing process of solder paste that bonds the substrate and the electronic component. In this way, a gap between the substrate and the electronic component can be maintained with a proper height during the reflowing process, which provides a channel or pathway that is sufficient for gas such as vaporized flux to escape and thereby improves bonding performance between the substrate and the electronic component.

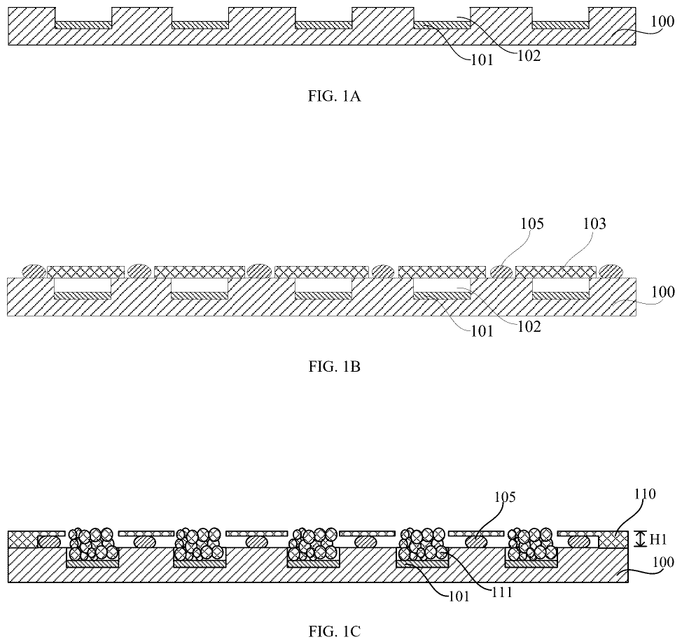

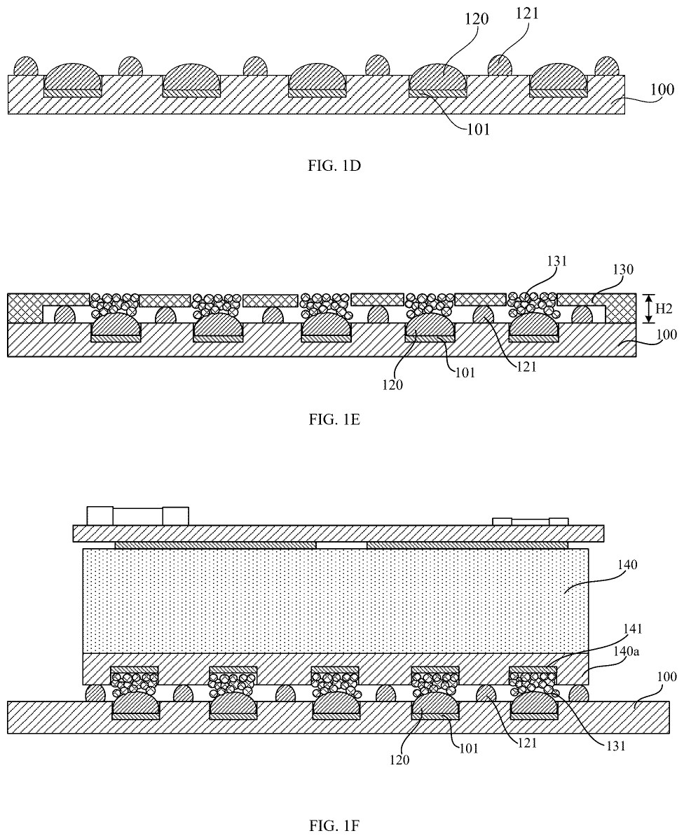

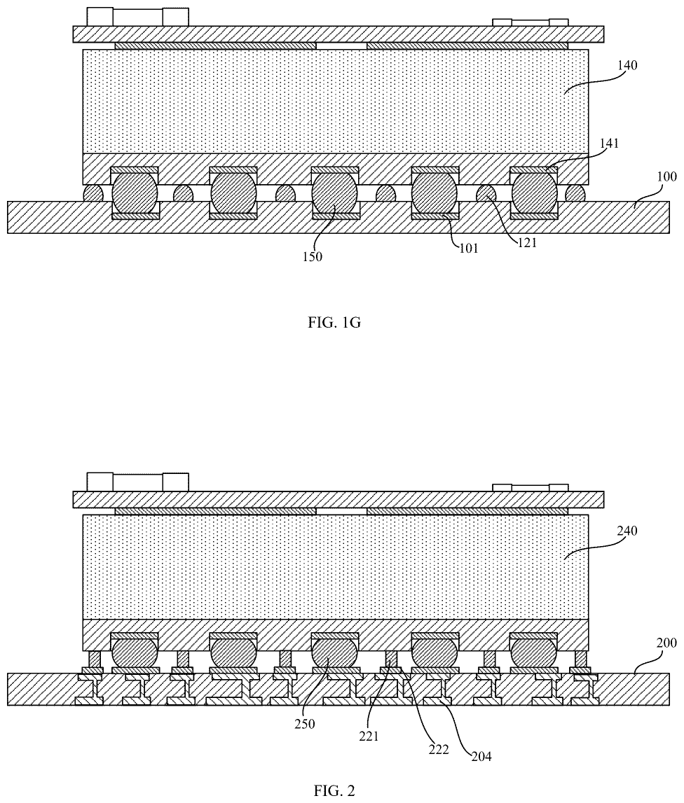

FIGS. 1A to 1G illustrate various steps of a method for forming an electronic device according to a first embodiment of the present application.

As shown in FIG. 1A, a package substrate 100 is provided with embedded interconnect wires (not shown). A first set of conductive pads 101 are formed on the package substrate 100 for mounting electronic component(s) thereon. The first set of conductive pads 101 may be electrically connected with a portion of the interconnect wires to allow electrical connection between the package substrate 100 and the electronic components. In the embodiment shown in FIG. 1A, the package substrate 100 may include a set of recesses 102 on its front surface, which may be formed by removing a top portion of the package substrate 100, for example, by a technique selected from at least one of etching, milling, drilling, pinching or their combinations. And each of the first set of conductive pads 101 may be formed within one of the set of recesses 102. In some other embodiments, the package substrate 100 may have a flat front surface, the first set of conductive pads 101 may be formed on the flat front surface of the package substrate 100 instead of being recessed into the package substrate 100. It can be appreciated that the first set of conductive pads 101 may be exposed portions of interconnect wires formed within the package substrate 100. In some embodiments, the package substrate 100 may be a printed circuit board (PCB), an interposer or other similar components.

As shown in FIG. 1B, a supporting component stencil 103 which is used to form supporting components is placed on the front surface of the package substrate 100. The supporting component stencil 103 includes a base portion which shields the first set of conductive pads 101 and multiple openings passing through the base portion. When the supporting component stencil 103 is placed on the package substrate 100, the openings can expose a portion of the front surface of the package substrate 100. In some embodiments, each of the openings exposes a portion of the package substrate 100 between two adjacent conductive pads 101, as is shown in FIG. 1B. Next, a supporting material 105 is deposited on the package substrate 100 through the openings of the supporting component stencil 103. Since the base portion of the supporting component stencil 103 blocks the supporting material 105 from flowing into the recesses 102, the first set of conductive pads 101 may not be contaminated by and deposited with the supporting material 105. In some embodiments, a portion of the package substrate 100 between two adjacent conductive pads is aligned with more than one opening of the supporting component stencil 103. The openings may be distributed either uniformly or non-uniformly in the supporting component stencil 103. It can also be appreciated that each of the openings may have a strip-shaped layout. The supporting material 105 serves as an ingredient to form supporting components in a subsequent process. The openings of the supporting component stencil 103 may be arranged differently depending on the desired layout of the supporting components to be formed on the package substrate 100.

In some embodiments, an excessive amount of the supporting material 105 may be applied on the supporting component stencil 103, so as to ensure that sufficient supporting material 105 can flow through the openings of the supporting component stencil 103 onto the package substrate 100. The excessive portion of the supporting material 105 that remains on the base portion of the supporting component stencil 103 may be removed, for example, by a scraper. In this way, a height of the supporting material 105 within each of the openings may be approximately the same, i.e., equaling the thickness of the openings. The uniform thickness of the supporting components formed subsequently can avoid tilting of an electronic component that may be mounted on the supporting components in a subsequent surface mounting process. As shown in FIG. 1B, the amount of the supporting material 105 applied on the package substrate 100 may be determined by a thickness of the supporting component stencil 103. It can be appreciated that the thickness of the supporting component stencil 103 should be high enough that a sufficient amount of the supporting material 105 can be applied and deposited on the package substrate 100 to form the supporting components. However, it is desired that the thickness of the supporting component stencil 103 should not be too high because the size of the solid bonding structures such as solder bumps between the package substrate 100 and an electronic component that may be mounted subsequently is pre-determined. For example, the thickness of the supporting component stencil 103 may be between 20 μm to 40 μm. In some embodiments, the supporting material 105 may include a thermosetting material, such as epoxy. The supporting material 105 is an insulative material which can be formed at any suitable position of the package substrate 100 regardless of a layout of the package substrate 100, without potential short-circuit risks. In some embodiments, the supporting material 105 may be cured by a heating process to form the supporting components. It can also be appreciated that the supporting material 105 may be cured in a subsequent process.

After the supporting components are formed on the package substrate 100, the solder paste can be deposited. In some embodiments, the solder paste can be deposited on the package substrate 100 in a single deposition process such as a stencil printing process. However, in some other embodiments, the solder paste can be deposited on the package substrate 100 in two or more deposition processes. Each of the deposition processes may be followed by a respective reflowing process to melt and reshape the solder paste formed in the previous deposition process, thereby improving the fusion between the solder paste and the underlying conductive pad.

In particular, as shown in FIG. 1C, a first solder stencil 110 may be placed on the package substrate 100. The first solder stencil 110 includes a base portion covering the supporting material 105 and a first set of solder openings passing through the base portion which expose the first set of conductive pads 101. A first portion of a solder material 111 is deposited on the first set of conductive pads 101 through the first set of solder openings of the first solder stencil 110. In the embodiment shown in FIG. 1C, the first portion of the solder material 111 may be accommodated within the recesses 102 to achieve good positioning of the first portion of the solder material 111. Similar as the supporting component stencil 103, an amount of the first portion of the solder material 111 applied on the first set of conductive pads 101 through each of the first set of solder openings may be determined by a thickness H1 of the first solder stencil 110. In some embodiments, the thickness H1 of the first solder stencil 110 may be between 60 μm to 100 μm.

In some embodiments, the first portion of the solder material 111 may be solder paste including flux mixed with metal powders. As shown in FIG. 1D, the first portion of the solder material 111 may be reflowed to form a first solder portion 120 on each of the first set of conductive pads 101. During a reflowing process (also referred to as a first reflowing process), the first portion of the solder material 111 may be heated to a high temperature such that the flux of the solder paste may be vaporized, and the vaporized or gaseous flux may be generated. The high temperature further induces the metal powders to melt, thereby forming the first solder portion 120 after the reflowing process. Since the first portion of the solder material 111 is exposed to an open space, the vaporized flux or other gas generated during the reflowing process may escape to the outside more easily, which avoids forming voids within the first solder portion 120.

Furthermore, as shown in FIG. 1D, during the reflowing process of the first portion of the solder material 111, the supporting material 105 may be heated and cured simultaneously with the solder paste, which may then be solidified into multiple supporting components 121, for example, as supporting balls or bumps. However, it can be appreciated that the supporting material 105 may be cured prior to the deposition of the solder material, for example, in a separate heating process.

As aforementioned, more solder material may be deposited on the package substrate 100. In particular, as shown in FIG. 1E, a second solder stencil 130 may be placed on the package substrate 100. The second solder stencil 130 includes a base portion covering the supporting components 121 and a second set of solder openings passing through the base portion which expose the first solder portion 120. A second portion of the solder material 131 is then deposited on the first portion of the solder material 111 (i.e., the first solder portion 120) through the second set of solder openings of the second solder stencil 130. It can be appreciated that the second solder stencil 130 may have the same or similar layout of solder openings as the first solder stencil, such that the solder openings of the two solder stencils can be both aligned with the first set of conductive pads 101 where the solder material is desired to be deposited. In some embodiments, during a subsequent reflowing process of the solder material, since a portion of the second portion of the solder material 131 may melt and flow downwards to the first set of conductive pads 101, the amount of the second portion of the solder material 131 remained at a higher position away from the package substrate 100 may be reduced. Therefore, the second set of solder openings through the second solder stencil may have a size larger than that of the first set of solder openings through the first solder stencil, so as to apply a larger amount of the second portion of the solder material 131 to compensate for the reduced amount of the second portion of the solder material 131 to form solder bumps with a uniform height after the reflowing process. In some preferred embodiments, the second set of solder openings may have a size which is 100% to 120% of that of the first set of solder openings.

Furthermore, similar as the first solder stencil, an amount of the second portion of the solder material 131 applied through each of the second set of solder openings may be determined by a thickness H2 of the second solder stencil 130. In some embodiments, the thickness H2 may be larger than the thickness H1 of the first solder stencil. To be more specific, the thickness H2 of the second solder stencil 130 may be between 80 μm to 120 μm. In some other embodiments, the thickness H2 may be smaller than or the same as the thickness H1 of the first solder stencil. Furthermore, the second portion of the solder material 131 may be solder paste including flux mixed with metal powders.

Next, as shown in FIG. 1F, an electronic component 140 is attached onto the package substrate 100, and in particular, being supported by the supporting components 121. In some embodiments, the electronic component 140 may include a large-scale semiconductor chip, an electronic package stack with multi-layer structures, or an electronic device or package having multiple electronic modules integrated therein. As such, the electronic component 140 may have a relatively heavy weight. To be more specific, the electronic component 140 may include a base substrate 140a and an electronic module mounted on the base substrate 140a. A second set of conductive pads 141 may be formed on the base substrate 140a. In the embodiment shown in FIG. 1F, the base substrate 140a may include a set of recesses on its front surface. Each of the second set of conductive pads 141 may be formed within one of the set of recesses, respectively. When the electronic component 140 is mounted onto the package substrate 100, each of the second set of conductive pads 141 is aligned with a respective one of the first set of conductive pads 101 to accommodate the second portion of the solder material 131 within the recesses of the base substrate 140a. In some other embodiments, the base substrate 140a may have a flat front surface, and the second set of conductive pads 141 may be formed on the front surface of the base substrate 140a instead of being recessed into the base substrate 140a.

A shown in FIG. 1F, the supporting components 121 may provide mechanical support for the electronic component 140 such that a sufficient gap may be created between the electronic component 140 and the package substrate 100 while the second set of conductive pads 141 may be in direct contact with the second portion of the solder material 131. In some embodiments, the supporting components 121 are formed before the attachment of the electronic component 140, and the electronic component 140 may be detachably disposed on the supporting components 121 without bonded with the electronic component 140. In some other embodiments, a plurality of concaves may be formed on the front surface of the base substrate 140a. To be more specific, each of the concaves may be aligned with a respective one of the supporting components 121 to receive a top portion of the supporting component 121 within the concave. As such, a position of the electronic component 140 relative to the package substrate 100 may be fixed, which reduces displacement and tilting of the electronic component 140 during a subsequent reflowing process. Also, the concaves may provide a more accurate and convenient alignment between the first set of conductive pads 101 and the second set of conductive pads 141 when the electronic component 140 is attached onto the package substrate 100.

Next, as shown in FIG. 1G, a second reflowing process may be implemented to reflow the second portion of the solder material 131 and optionally the first solder portion 120. During the second reflowing process, the second portion of the solder material 131 may be heated to a high temperature such that the flux may be volatilized, and gas may be generated again. The high temperature further induces the first solder portion 120 and the metal powders within the second portion of the solder material 131 to melt and be reshaped together, thereby forming an integral solder bump 150 between each pair of conductive pad 101 and conductive pad 141 after the second reflowing process. As such, the electronic component 140 may be electrically connected with the package substrate 100 through the first set of conductive pads 101, the integral solder bumps 150 and the second sets of conductive pads 141.

During the second reflowing process, the electronic component 140 is supported by the supporting components 121 which prevent the electronic component 140 from collapsing onto the package substrate 100. As such, a sufficient gap between then package substrate 100 and the electronic component 140 can be maintained due to the mechanical support provided by the supporting components 121, which allows for an enlarged or appropriate channel for the vaporized flux or other gas to escape. Furthermore, as aforementioned, the first portion of the solder material 111 has been reflowed during the first reflowing process which is prior to the second reflowing process, and the flux included within the first portion of the solder material 111 has been released from the solder bumps so formed. Therefore, a total ratio of the metal powder within the second portion of the solder material 131 and the first solder portion 120 may increase. On the contrary, a total ratio of the flux within the second portion of the solder material 131 and the first solder portion 120 may decrease, which may further suppress gas generated during the second reflowing process. In other words, a less amount of gas may be generated during the second reflowing process and the generated gas can escape more easily through the enlarged ventilation channel. After the second reflowing process, potential voids within the integral solder bumps 150 may be reduced compared with solder bumps formed using an existing method, resulting in a better bonding performance between the package substrate 100 and the electronic component 140. Also, metal beadings between the electronic component 140 and the package substrate 100 may be eliminated, which further avoid or reduce short-circuit risks.

Furthermore, since the supporting components 121 can effectively maintain the electronic component 140 spaced away from the package substrate 100 and thus result in minor deformation of the solder material at least along the front surface of the package substrate 100, the supporting components 121 can further prevent two adjacent solder bumps 150 from flowing into each other and forming a solder bridge which are undesired. Moreover, after the formation of the integral solder bumps 150, the supporting components 121 may continue to provide mechanical support for the electronic component 140, which avoids subsequent deformation of the integral solder bumps 150 due to the pressure applied by the electronic component 140.

In some embodiments, a height of the supporting components 121, which is defined by the thickness of the supporting component stencil 103, may be positively correlated with a weight of the electronic component 140. That is to say, the heavier or bigger the electronic component 140 is, the higher the supporting components 121 may be. Moreover, a ratio in amount between the second portion of the solder material 131 and the first portion of the solder material 111 may be adjusted by properly setting the thickness H2 of the second solder stencil 130 and the thickness H1 of the first solder stencil 110, such that a desired ratio of the flux used within the second portion of the solder material 131 and the first solder portion 120 during the second reflowing process can be achieved.

In some other embodiments, instead of the two-step reflowing process as illustrated in FIGS. 1C to 1G, a one-step reflowing process is implemented to form enhanced electrical connections between the electronic component and the package substrate. To be more specific, a plurality of supporting components may first be formed on a package substrate. Next, a solder material may be deposited onto the package substrate and an electronic component may be attached onto the supporting components. Next, the solder material is reflowed to form solder bumps, which connect the electronic component with the package substrate. The electronic component is supported by the supporting components during the reflowing process to create a sufficient gap for gas generated to escape more easily.

FIG. 2 illustrates an electronic device according to a second embodiment of the present application. The electronic device shown in FIG. 2 has a structure and a forming process similar as the electronic device shown in FIGS. 1A to 1G, except that the supporting components 221 included in the electronic device in FIG. 2 are metal spacers instead of the supporting components 121 formed of a curable material (e.g., epoxy) as illustrated in FIGS. 1A to 1G.

To be more specific, as shown in FIG. 2, the metal spacers 221 are formed on a package substrate 200, and each of the metal spacers 221 is connected with at least a portion of interconnect wires 204 embedded within the package substate 200 through a respective conductive pad 222. In some embodiments, the metal spacers 221 may include stainless steel, aluminum, brass or bronze. Similar as the supporting components 121 illustrated in FIGS. 1A to 1G, the metal spacers 221 may support an electronic component 240 during a reflowing process, so as to form solder bumps 250 and to maintain a sufficient gap between a package substrate 200 and the electronic component 240 during the reflowing process. The gap can provide an enlarged channel for gas generated during the reflowing process to escape to the outside, and therefore improves bonding performance between the package substrate 200 and the electronic component 240.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, the method comprising:
providing a package substrate with a first set of conductive pads formed thereon;
forming supporting components on the package substrate without covering the first set of conductive pads;
depositing a solder material onto the first set of conductive pads;
mounting an electronic component having a second set of conductive pads onto the package substrate to align each of the first set of conductive pads with one of the second set of conductive pads; and
reflowing the solder material to electrically connect the electronic component with the package substrate through the first and second sets of conductive pads, wherein the electronic component is supported by the supporting components during the reflowing.

2. The method of claim 1, wherein the supporting components comprise a thermosetting material.

3. The method of claim 2, wherein forming supporting components on the package substrate comprises:
placing on the package substrate a supporting component stencil having openings passing therethrough and not aligned with the first set of conductive pads;
depositing a supporting material on the package substrate through the openings of the supporting component stencil; and
curing the supporting material to form the supporting components.

4. The method of claim 3, wherein the supporting component stencil has a thickness such that the supporting components are sufficient to support the electronic component on the package substrate during the reflowing.

5. The method of claim 4, wherein the thickness of the supporting component stencil is between 20 μm to 40 μm.

6. The method of claim 1, wherein depositing a solder material onto the first set of conductive pads comprises:
placing a first solder stencil having a first set of solder openings passing therethrough on the package substrate to expose the first set of conductive pads on the package substrate through the first set of solder openings but cover the supporting components by the first solder stencil;
depositing a first portion of the solder material on the first set of conductive pads through the first set of solder openings of the first solder stencil;
reflowing the first portion of the solder material;
placing a second solder stencil having a second set of solder openings on the package substrate to expose the first portion of the solder material through the second set of solder openings but cover the supporting components by the second solder stencil; and
depositing a second portion of the solder material on the first portion of the solder material through the second set of solder openings of the second solder stencil.

7. The method of claim 6, wherein a thickness of the second solder stencil is larger than that of the first solder stencil.

8. The method of claim 7, wherein the thickness of the first solder stencil is between 60 μm to 100 μm; and the thickness of the second solder stencil is between 80 μm to 120 μm.

9. The method of claim 6, wherein the first portion of the solder material comprises flux and metal powders; and the second portion of the solder material comprises flux and metal powders.

10. The method of claim 6, wherein the supporting components comprise a thermosetting material, and the method further comprises: during the reflowing of the first portion of the solder material, the supporting components are being cured simultaneously.

11. The method of claim 1, wherein the first set of conductive pads are recessed into the package substrate and the second set of conductive pads are recessed into the electronic component.

12. An electronic device, comprising:
a package substrate with a first set of conductive pads formed thereon;
supporting components formed on the package substrate and exposing the first set of conductive pads;
an electronic component mounted on the package substrate via solder bumps and the supporting components, wherein the electronic component has a second set of conductive pads each being aligned with one of the first set of conductive pads and connected with the conductive pad via one of the solder bumps, and wherein the electronic component is electrically coupled to the package substrate through the first and second sets of conductive pads and the solder bumps therebetween.

13. The electronic device of claim 12, wherein the supporting components comprise a thermosetting material.

14. The electronic device of claim 12, wherein the first set of conductive pads are recessed into the package substrate and the second set of conductive pads are recessed into the electronic component.
